(19) United States
(12) Patent Application Publication
(10) Pub. No.: US 2005/0158477 A1
(43) Pub. Date: Jul. 21, 2005

(54) Deposition apparatus and a deposition method using medium in a supercritical state

(75) Inventors: Vincent Vezin, Kyoto-Shi (JP); Kenichi Kubo, Kofu-Shi (JP); Takayuki Komiya, Nirasaki-Shi (JP); Eiichi Kondoh, Kai-Shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignees: TOKYO ELECTRON LIMITED, Tokyo (JP); EIICHI KONDOH, Kai-Shi (JP)

(21) Appl. No.: 11/017,848

(22) Filed: Dec. 22, 2004

(30) Foreign Application Priority Data
Dec. 25, 2003 (JP) 2003-430575

(51) Int. Cl. C23C 16/00; B05C 11/00

(52) U.S. Cl. 427/430.1; 427/248.1; 118/667

(57) ABSTRACT

A deposition apparatus for supplying a process medium including a medium in a supercritical state and a precursor to a processed substrate so that the processed substrate is deposited on, includes a process vessel, a support stand which is provided in the process vessel, is configured to support the processed substrate, and include a heating part, a medium supply part which is connected to the process vessel via a medium supply path and supplies the process medium to the process vessel, and a medium reflux path configured to reflux the process medium supplied to the process vessel to the medium supply part. The medium supply part includes a first temperature control part configured to control a temperature of the process medium.

### BACKGROUND OF THE INVENTION

1. Field of the Invention

The present invention generally relates to deposition apparatuses and deposition methods, and more specifically to a deposition apparatus and a deposition method using a medium in a supercritical state.

2. Description of the Related Art

Recently and continuing, as performance and function of semiconductor devices are becoming high, high integration of the semiconductor devices are being promoted and it is extremely desired that the semiconductor devices have fine structures. A wiring rule is being improved from an area of 0.13 μm to 0.10 μm. A fine wiring technology is now an important key technology for fine multilayer wiring.

There is a tendency that copper (Cu) is used as a wiring material for the semiconductor device. This is because Cu has a resistance value lower than a resistance value of aluminum (Al). A spattering method, chemical vapor deposition (CVD) method, plating method, or the like is generally known as a deposition method for Cu. However, each method has a limitation in coverage on the fine wiring and therefore it is extremely difficult to efficiently deposit on a fine pattern having a high aspect ratio and a length less than 0.1 μm, or form Cu wiring by, for example, deposition of Cu.

Because of this, a method for depositing on the fine pattern using a medium in a supercritical state is suggested as a method for efficiently depositing on the fine pattern. See, for example, “Deposition of Conformal Copper and Nickel Films from Supercritical Carbon Dioxide” SCIENCE Vol. 294, Oct. 5, 2001. According to the above-mentioned publication, a precursor chemical compound (hereinafter “precursor”) including Cu for depositing Cu is dissolved by using CO₂ in a supercritical state so that Cu is deposited on the fine pattern. Here, the supercritical state means a state where a material has specific features of gas and liquid when the temperature and pressure of the material become higher than a critical point, namely a value peculiar to the material.

For example, in the above-mentioned media in the supercritical state of CO₂, Cu deposition precursor, namely a precursor chemical compound including Cu, has a high dissolution while it has a low viscosity and high diffusion. Therefore, it is possible to deposit Cu on the above-mentioned fine pattern having a high aspect ratio.

However, the precursor dissolved in the supercritical state so as to be used, such as the precursor used for deposition of Cu, is high-priced. This causes an increase of a deposition cost. A ratio for discharging a medium in a supercritical state, wherein a precursor is dissolved, from a process vessel in which the medium is supplied for deposition, is higher than a ratio for using the medium for deposition. Thus, the efficiency of utilization of the precursor is low and therefore this causes an increase of the deposition cost.

Furthermore, the medium in the supercritical state has a high density. When the medium becomes gas at atmospheric pressure, the volume of the medium is high. For example, if a large volume of CO₂ in the supercritical state is discharged, since the large volume of CO₂ is consumed, this causes not only the increase of the deposition cost but also a bad effect on the environment.

In addition, when deposition is implemented by using the medium in the supercritical state, a part other than a processed substrate which is a subject of deposition, such as an internal wall of the process vessel, is deposited on. This causes a lot of time to be expended for changing parts or performing maintenance so that productivity may be reduced.

### SUMMARY OF THE INVENTION

Accordingly, it is a general object of the present invention to provide a novel and useful deposition apparatus and deposition method whereby a utilization efficiency of a precursor used for deposition is improved so that costs for deposition can be reduced, in which one or more of the problems described above are eliminated.

Another object of the present invention is to provide a deposition apparatus and deposition method whereby an amount of a medium in a supercritical state which is consumed by the deposition is reduced so that costs for deposition and bad influence to an environment can be reduced.

It is also other object of the present invention to provide a deposition apparatus and deposition method whereby an amount deposited on a part other than a processed substrate which is a subject of deposition is reduced so that a productivity of deposition process can be improved.

The above objects of the present invention are achieved by a deposition apparatus for supplying a process medium including a medium in a supercritical state and a precursor to a processed substrate so that the processed substrate is deposited on, including:
a process vessel;
a support stand which is provided in the process vessel, is configured to support the processed substrate, and include a heating part;
a medium supply part which is connected to the process vessel via a medium supply path and supplies the process medium to the process vessel; and
a medium reflux path configured to reflux the process medium supplied to the process vessel to the medium supply part;
wherein the medium supply part includes a first temperature control part configured to control a temperature of the process medium.

The above objects of the present invention are also achieved by a deposition method for depositing on a processed substrate supported in a process vessel, including the steps of:
a) supplying a process medium including a medium in a supercritical state and a precursor to the process vessel;
b) depositing on the processed substrate by the process medium;
c) cooling the process medium discharged from the process vessel; and
d) supplying the process medium cooled in the step c) to the process vessel.

Other objects, features, and advantages of the present invention will become more apparent from the following detailed description when read in conjunction with the accompanying drawings.

### BRIEF DESCRIPTION OF THE DRAWINGS

FIG. 1 is a schematic view of a deposition apparatus of a first embodiment of the present invention;

FIG. 2 is a first flowchart showing a deposition method according to a second embodiment of the present invention;

FIG. 3 is a second flowchart showing a deposition method according to the second embodiment of the present invention;

FIG. 4 is a first view showing manufacturing steps of a semiconductor device using the deposition method according to the second embodiment of the present invention; and

FIG. 5 is a second view showing manufacturing steps of the semiconductor device using the deposition method according to the second embodiment of the present invention.

### DETAILED DESCRIPTION OF THE PREFERRED EMBODIMENTS

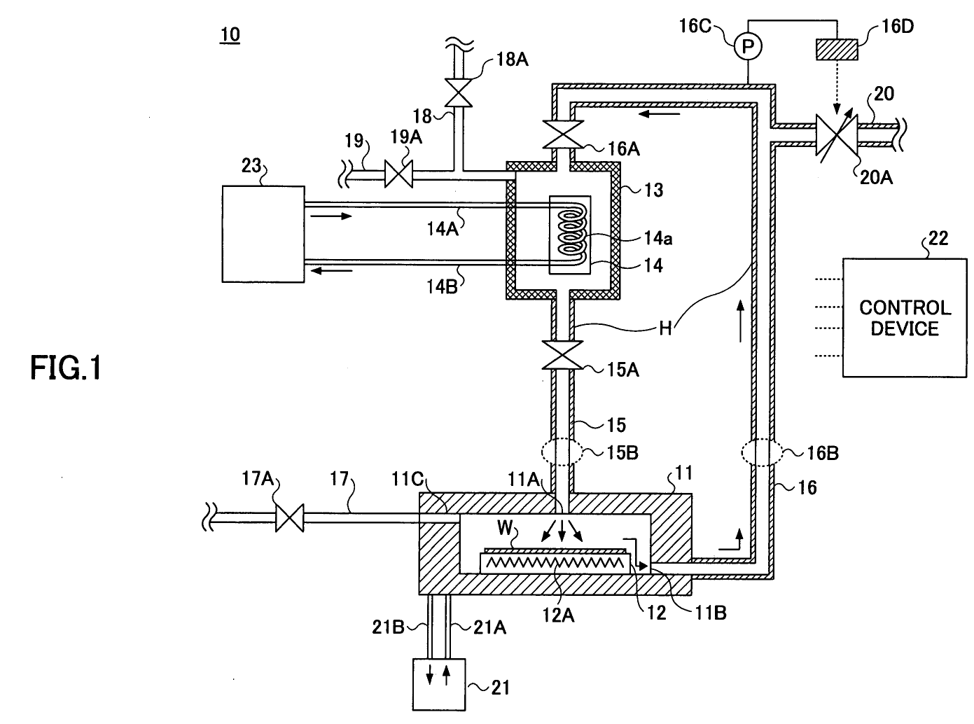

A description will now be given, with reference to FIG. 1 through FIG. 5, of embodiments of the present invention.

### Principle

There are three phases, namely a vapor phase, a liquid phase, and a solid phase, in material. In addition to the three phases, there is a supercritical fluid phase wherein it is not possible to change the material to liquid even if the pressure is raised more in a state where the temperature and the pressure have values higher than peculiar values, or wherein it is not possible to change the material to gas even if the temperature is raised more in a state where the temperature or the pressure have values higher than peculiar values.

A pressure condition or a temperature condition peculiar to the material is called a critical point. In the material in the supercritical state, it is possible to dramatically change a physical property, such as density, viscosity, or diffusion coefficient, from a state close to gas state to a state close to a liquid state by changing the temperature or the pressure.

Because of this, in a case where the material in the supercritical state is used as a medium, since the material has a density and dissolution close to liquid, it is possible to keep the dissolution of a precursor high, as compared to a gas medium. Furthermore, by using a diffusion coefficient close to gas, it is possible to convey the precursor to the processed substrate more efficiently than the liquid medium. Therefore, in a deposition wherein a process medium made by dissolving the precursor in the medium in the supercritical state is used, a deposition rate can be made high and a good coverage of the fine pattern by the deposition can be obtained.

By the present invention, an apparatus and a method whereby utilization efficiency of the process medium made by dissolving the precursor in the medium in the supercritical state can be further improved. In a deposition using the present invention, the process medium discharged from the process vessel is cooled and refluxed to the process vessel, while the process medium is supplied to the process vessel for deposition and deposition is implemented.

According to the present invention, it is possible to increase a ratio of the precursor contributing to the deposition and improve utilization efficiency of the precursor. Hence, it is possible to prevent an amount of use of the precursor from being increasing so that deposition cost can be reduced. Furthermore, it is possible to reduce the consumption amount of a medium in the supercritical state which is used in dissolving the precursor. Therefore, it is possible to reduce costs for deposition and a bad effect on the environment when the medium is discharged.

Furthermore, a cooled process medium is supplied by cooling the refluxed process medium and therefore a deposition on a part other than the processed substrate which is the subject of deposition, due to a chemical reaction such as a heat decomposition of the precursor, is prevented. This results a highly efficient deposition.

### First Embodiment

Next, a deposition apparatus used for the present invention is discussed with reference to FIG. 1.

FIG. 1 is a schematic view of a deposition apparatus of a first embodiment of the present invention.

Referring to FIG. 1, a deposition apparatus 10 includes a process vessel 11. A support stand 12 is provided inside of the process vessel 11 so as to support a processed substrate W. A heater is embedded in the support stand 12. A medium supply part 13 supplying a process medium to the process vessel 11 is connected to the process vessel 11 via a medium supply path 15 having a valve 15A.

A medium made by dissolving a precursor in a medium in a supercritical state, namely the process medium, fills into the medium supply part 13. The temperature of the process medium is controlled by a first temperature control part 14 provided in the medium supply part 13. The first temperature control part 14 has a box having a high coefficient of thermal conductivity, for example. A heat exchange flow path 14a for heat exchange is formed inside of the box. The first temperature control part 14 may omit the box.

The heat exchange flow path 14a is connected to a circulation apparatus 23 via an introducing path 14A and a discharge path 14B. A cooling mechanism and a heating mechanism are provided inside of the circulation apparatus 23. If necessary for temperature control, for example, a heat exchanging fluid, made of a fluorocarbon group fluid, is heated or cooled and a process medium inside of the medium supply part 13 is heated or cooled so that temperature control of the process medium is implemented.

A line 18 having a valve 18A and a line 19 having a valve 19A are connected to the medium supply part 13. A medium where the precursor is dissolved, a medium where bis-hexafluoroacetylacetonate copper (II) (hereinafter “Cu²⁺(hfac)₂”) is dissolved in a case where Cu is to be deposited for example, is introduced from the line 19. In this case, CO₂ is used as a medium for dissolving the precursor, for example.

For example, in the case of CO₂, the critical point (which is a point for a supercritical state) is a temperature 31.0° C. and a pressure 7.38 MPa. When a temperature and a pressure are higher than the critical point, CO₂ becomes a supercritical state. In a case where the precursor is introduced into the medium supply part 13, for example, a process medium, namely the medium in the supercritical state where the precursor is dissolved is introduced from the introduction path 19 by opening the valve 19A.

A CO₂ supply source, a compressing part (pressurizing part) and a mixture part for the precursor and CO₂ (not shown in FIG. 1) are connected to the line 19. The process medium is supplied from the line 19 to the medium supply part 13 so as to fill the medium supply part 13. In this case, it is preferable that the precursor be dissolved in the process medium at a certain definite density, for example in a saturation solution state, in order to manage a supplying amount of the precursor.

A CO₂ supply source and reducer supply source (not shown in FIG. 1) are connected to the line 18 which is connected to the medium supply part 13.

CO₂ or a reducer for reducing the precursor, for example H₂ in a case where Cu²⁺(hfac)₂ is used as the precursor, is supplied from the line 18 to the medium supply part 13 by opening the valve 18A. The reducer may be unnecessary in a case where an organometallic complex adduct including a monatomic copper ion is used as the precursor.

The medium supply part 13 may be pressurized by CO₂ supplied from the line 18 before the process medium is supplied from the line 19 to the medium supply part 13 so that CO₂ inside of the medium supply part 13 can be in the supercritical state in advance. Furthermore, the inside of the medium supply part 13 may be purged by CO₂ supplied from the line 18.

The reducer or a medium in a supercritical state including the reducer may be introduced in advance before the medium in the supercritical state where the precursor is dissolved fills the medium supply part 13 so that the process medium and the medium in the supercritical state including the reducer may be mixed inside of the medium supply part 13.

The process medium filling the medium supply part 13 is introduced in the process vessel 11 from the medium supply path 15 through the supply opening part 11A of the process vessel 11 by opening the valve 15A. The support stand 12 supporting the wafer W is provided in the process vessel 11.

The wafer W supported on the support stand 12 is heated by the heater 12A. The temperature of the wafer W is kept higher than a temperature at which a chemical reaction due to heating of the precursor starts, in the range 180° C. through 400° C., depending on the kind of the introduced precursor. A Cu film is formed on the wafer W because the precursor dissolved in the process medium such as Cu²⁺(hfac)₂ undergoes a chemical reaction or decomposition due to heat.

A material for deposited film varies depending on the precursor to be used. A chemical reaction due to heat such as dissociation, association, oxidation, reduction, disproportionation, or the like occurs depending on the precursor to be used.

In addition, the medium in the supercritical state, such as CO₂ in the supercritical state, has extremely high flowability and diffusion. Therefore, for example, in a case where Cu film is formed on the fine pattern having the length shorter than 0.1 μm, it is possible to efficiently form a Cu film so that a good coverage property and an embedding property can be obtained.

The process medium supplied to the process vessel 11 is discharged from the discharged opening part 11B formed in the process vessel 11 so as to be refluxed from the medium reflux path 16 connected to the discharging opening part 11B to the medium supply part 13.

A valve 16A is provided in the medium reflux path 16. The process medium supplied to the process vessel 11 is refluxed to the medium supply part 13 by opening the valve 16A. In the medium supply part 13, the refluxed process medium is cooled by the temperature control part 14 and supplied from the medium supply path 15 to the process vessel 11 again.

That is to say, the process medium is refluxed from the medium supply part 13 to the process vessel 11, then from the process vessel 11 to the medium supply part 13, and then to the process vessel 11 so that deposition on the processed substrate is done.

In this case, the process medium is heated via the wafer W heated when supplied to the process vessel 11. Hence, there may be a problem in that the temperature of the process medium may gradually rise as the process medium is being refluxed. If the temperature of the process medium rises so as to reach a temperature at which a chemical reaction due to heat of the precursor occurs, such as a heat decomposition temperature, a problem that an internal wall of the process vessel 11, the medium reflux path 16, or the medium supply path 15 is deposited on, may occur.

Hence, in this embodiment, a temperature control mechanism 14 as the first temperature control part 14 is provided at the medium supply part 13 so that the temperature of the process medium is controlled. In this case, the process medium is cooled by the temperature control mechanism 14 so that the temperature of the process medium is prevented from rising and therefore the process medium is circulated in a certain definite temperature range.

Because of this, a density difference of the process medium due to the temperature difference is generated in a direction from the medium supply part 13 where the temperature of the process medium is low to the process vessel 11 where the temperature of the process medium is high. Based on the density difference, a flow is generated so that a circulation of the process medium occurs. As a result of this, it is possible to make a state where the process medium is circulated without using compression means such as a pump.

However, in a case where it is necessary to raise the speed for circulating the process medium depending on a deposition condition or a temperature condition, if necessary, a compression part 15B may be added to the medium supply path 15 or a compression part 16B may be added to the medium reflux path 15. In this case, it is possible to raise the speed for circulating the process medium.

Thus, the deposition apparatus 10 includes a mechanism for circulating the process medium for deposition. Hence, as compared to a conventional method whereby the process medium is discharged while it is continuously supplied, the present invention has an advantage in that it is possible to increase the ratio of the precursor contributing to the deposition. Therefore, it is possible to improve utilization efficiency of the precursor. Hence, it is possible to prevent an amount of use of the precursor which is expensive from being increased so that deposition cost can be reduced.

Furthermore, it is possible to reduce the consumption amount of the medium dissolving the precursor such as CO₂ in the supercritical state. Therefore, it is possible to reduce costs for deposition and the bad effect on the environment.

A circulation device 21 as a second temperature control part is connected to the process vessel 11 so as to control the temperature of an internal wall of the process vessel 11. The circulation device 21 is connected to a heat exchange path (not shown in FIG. 1) which is formed inside of the process vessel 11, via an introduction path 21A and the discharge path 21B. A cooling mechanism and a heating mechanism are provided inside of the circulation device 21. The circulation device 21, if necessary for temperature control, for example, heats or cools a heat exchanging fluid, made of a fluorocarbon group fluid and heats or cools the process vessel via the heat exchange fluid, so that the temperature of the process vessel 11 is controlled.

For example, since the medium in the supercritical state is used as a solvent, it is preferable that the temperature of the process vessel 11 be controlled so as to be equal to or higher than the critical point of the solvent such as CO₂ (31C). Furthermore, if the temperature of the process vessel 11 rises too high, an internal wall surface of the process vessel 11 is deposited on by the chemical deposition due to the heat of the precursor. Hence, it is preferable that the temperature of the internal wall of the process vessel 11 be set so as to be equal to or lower than a temperature at which the chemical deposition due to heat of the precursor occurs, so that deposition on the internal wall of the process vessel 11 is prevented.

Because of this, in this embodiment, when Cu is deposited in a state where CO₂ is used as the medium in the supercritical state, Cu²⁺(hfac)₂ is used as the precursor, and H₂ is used as the reducer, the temperature of the internal wall of the process vessel 11 is controlled so as to be equal to or higher than 31° C. and equal to or lower than 160° C. and the temperature of the process vessel is kept at about 60° C.

Thus, by controlling the temperature of the process vessel 11, the solvent of the precursor is kept in the supercritical state and deposition by the precursor is prevented on a place other than the wafer W such as the internal wall of the process vessel 11, and deposition on the wafer W is done.

Furthermore, as a control of the temperature of the process vessel 11, other than use of the circulation device, the heater may be installed in the process vessel 11. In this case, it is preferable that control of electric power applied to the heater be done by using a control device corresponding to the temperature of the process vessel 11 measured by the temperature measurement part.

In addition, the temperature of the medium supply path 15 and the medium reflux path 16 is controlled by a temperature control part H as a third temperature control part for a reason the same as the reason for controlling the temperature of the process vessel 11. That is to say, in order to keep the supercritical state of the solvent dissolving the precursor, such as CO₂, or prevent deposition on the internal wall of the medium reflux path 16 due to decomposition of the precursor, the temperature of the medium supply path 15 and the medium reflux path 16 is controlled so as to be equal to or higher than 31° C. and equal to or lower than 160° C. and kept at about 60° C. Therefore, when the process medium is circulated, the solvent of the precursor is kept in the supercritical state and the precursor is prevented from depositing on a place other than the wafer W such as the internal wall of the medium supply path 15 and the medium reflux path 16, and deposition on the wafer W is done.

A line 17 having a valve 17A is connected to the process vessel 11. A CO₂ supply source and a compressing part (not shown in FIG. 1) are connected to the line 17. For example, pressure in the process vessel 11 can be raised by introducing CO₂ to the process vessel 11 by opening the valve 17A prior to introduction of the process medium to the process vessel 11. Furthermore, for example, it is possible to purge inside of the process vessel 11 by using CO₂ in the supercritical state after a deposition process is completed.

A medium discharge path 20 having a back pressure valve (dwelling valve) 20A is connected to the medium reflux path 16. By opening the back pressure valve (dwelling valve) 20A, it is possible to discharge the process medium remaining in the process vessel 11 or the medium supply part 13 after deposition is completed, or a by-product from the medium discharge path 20.

Furthermore, the medium reflux path 16 functions as a discharge part configured to purge the process vessel 11 or the medium supply part 13 after deposition is completed. For example, it is possible to introduce CO₂ in the supercritical state from the line 17, purge the process vessel 11 or the medium supply part 13, and discharge the remaining process medium or by-product from the medium discharge part 20 by the medium in the supercritical state. In this case, opening of the back pressure valve 20A is adjusted so that the purging medium keeps pressure in the supercritical state.

A pressure measured by a pressure gauge 16C provided in the medium reflux path 16 is fed back to a control part 16D so that the control part 16D adjusts the opening of the back pressure valve 20A. If necessary, pressure in the reflux path 16, the process vessel 11, or the medium supply part 13 is adjusted. The pressure is adjusted so that the purged medium or process medium is in the supercritical state in a case where the process medium is discharged or the process medium is purged by the medium in the supercritical state.

The medium in the supercritical state has high dissolution and diffusion. Therefore, as compared to a normal medium such as a case where purging is done by CO₂ gas, the medium in the supercritical state has a good purging efficiency. Hence, it is possible to efficiently purge the residue product such as the precursor remaining in the reflux path 16, the process vessel 11, or the medium supply part 13, or the by-product.

Control for opening and closing of the valves of the deposition apparatus or control with respect to the deposition process such as temperature control is done by a control device 22 whose electric wiring is omitted from being illustrated in FIG. 1.

### Second Embodiment

Next, an example of a deposition method using the deposition apparatus 10 is discussed in detail.

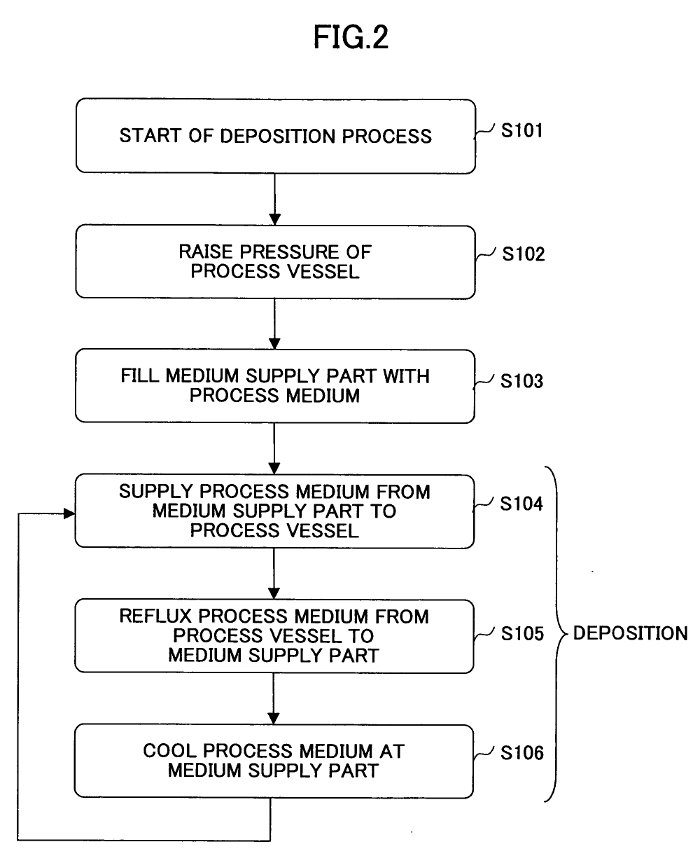

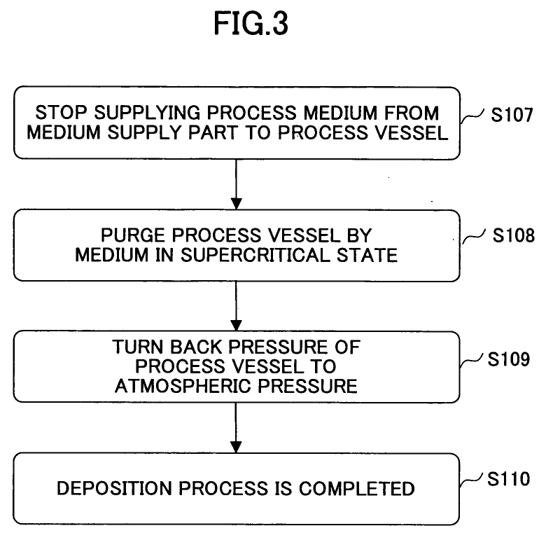

FIG. 2 and FIG. 3 are flowcharts showing a deposition method for depositing on the processed substrate by using the deposition apparatus 10.

Referring to FIG. 2, as starting a deposition process in step 101, an inside of the process vessel 11 where the wafer W which is a processed substrate, is supported on the support stand 12, and an inside of the medium supply part 13 are vacuum discharged by the medium discharge path 20. Then, in step 102, the valve 17A is opened so that CO₂ is introduced in the process vessel 11 so that a pressure in the process vessel is raised. In this case, CO₂ made to be in the supercritical state in advance may be introduced. Furthermore, CO₂ may be made to be in the supercritical state in the process vessel 11 by continuously supplying CO₂ liquid to the process vessel 11 so that the pressure of supplied CO₂ is raised or by raising the temperature of CO₂.

In the step 102, for example, pressure in the process vessel 11 is set to be 15 MPa. In this case, the density of CO₂ in the vicinity of a wall surface of the process vessel 11 controlled at a temperature of 60° C. becomes 13.7 mol/l. Since the temperature of the support stand 12 is, for example, controlled to be 250° C. by the heater 12A, the density of CO₂ in the vicinity of the support stand 12 becomes 3.7 mol/l.

Next, in step 103, the valve 19A is opened so that CO₂ which is a medium dissolving the precursor and Cu²⁺(hfac)₂ which is a precursor dissolved in the medium are supplied from the line 19 to the medium supply part 13. In this case, the medium is in the supercritical state or liquid. It is preferable that the precursor be dissolved in the medium at a definite concentration, in a saturation state, for example. The pressure of the medium supply part 13 may be raised by introducing CO₂ from the line 18 in advance before the medium supply part 13 is filled with the process medium.

In this case, H₂ which is a reducer may fill the medium supply part 13 in advance before the process medium is introduced.

Furthermore, the supercritical state can be attained by raising the temperature of CO₂ with the temperature control part, for example, after CO₂ not in supercritical state, such as CO₂ liquid, and the precursor are supplied to the medium supply part 13. Thus, in a case where it is difficult to supply the medium in the supercritical state, it is effective to raise the pressure of the process medium by heating the process medium by using the temperature control part 14 after the process medium is supplied to the medium supply part 13.

In the step 103, the pressure in the medium supply part 13 is controlled to be 15 MPa, the temperature of the process medium is controlled to be 40° C., and density of CO₂ is controlled to be 17.7 mol/l.

Next, in step 104, the valve 15A is opened so that the process medium is supplied from the medium supply part 13 to the medium supply path 15 and into the process vessel 11 via the supply opening part 11A. In this case, the following reaction occurs on the wafer W heated at 250° C. by the heating part 12A so that the precursor is heat-decomposed and a Cu film is deposited on the wafer W.

Cu²⁺(hfac)₂+H₂→Cu+2H (hfac)

CO₂ in the supercritical state under this pressure has a high dissolution of the precursor used for deposition. The process medium where the precursor is dissolved has a high diffusion. Hence, deposition speed is high and therefore it is possible to perform deposition whereby good coverage of the fine pattern is obtained.

For example, it is possible to form the Cu film on the fine pattern having a line thickness equal to or smaller than 0.1 μm and formed by an insulation film, with a good drape and embed-ability at a high deposition speed, without forming a space such as a void.

Next, in step 105, the valve 16A is opened so that the process medium in the process vessel 11 is refluxed from the discharge opening part 11B to the medium supply part 13 via the medium reflux path 16. In this case, the valve 16A may be opened at the same time that the valve 15A is opened. Furthermore, the valve 16A may be opened after the valve 15A is opened.

There is a temperature difference of the process medium in between the medium supply part 13 and the process vessel 11. Therefore, a reflux flow of the process medium from the medium supply part 13 to the process vessel 11 via the medium supply path 15 and from the process vessel 11 to the medium supply part 13 via the medium reflux path 16 is formed based on a density difference of the process medium.

Because of this, it is not necessary to provide equipment for refluxing such as compressing means, and the process medium can be circulated under a simple structure. In addition, it is possible to raise the circulation speed of the process medium by adding a compressing part 15B to the medium supply path 15 or adding a compressing part 16B to the medium reflux path 16.

In step 106, the process medium refluxed from the process vessel 11 to the medium supply part 13 is cooled by the temperature control part 14 at about 40° C. The process medium supplied in the process vessel 11 is heated at the medium introduction path 15 or the process vessel 11. Since the support stand 11 and the wafer W have a high temperature such as 250° C., the temperature of the process medium is raised.

For example, in a case where the refluxed process medium is not cooled, a density difference generated by a temperature difference in between the medium supply part 13 and the process vessel 11 is made small and therefore the circulation of the process medium is not done well. Because of this, the process medium is cooled at the medium supply part 13 so that the density difference generated by a temperature difference in between the medium supply part 13 and the process vessel 11 is formed and the process medium is circulated well.

Furthermore, if the temperature of the process medium is raised, heat decomposition of the precursor occurs so that Cu is formed on a place other than the wafer W, such as the internal wall of the process vessel 11, the medium supply path 15, or the medium reflux path 16. As a countermeasure against this, the temperature of the process medium is controlled, by cooling the process medium by the temperature control part 14 so that deposition on the wafer W is selectively done.

Furthermore, the process medium includes CO₂ in the supercritical state and the temperature of the critical point of CO₂ is 31° C. In a case where the process medium is cooled, it is necessary to make the temperature of the process medium have a temperature higher than the temperature of the critical point. Because of this, in this embodiment, the process medium in the medium supply part 13 is set to have a temperature equal to or higher than 31° C., for example, approximately 40° C.

The above-discussed steps 104 through 106 structure a process performed substantially in parallel. During the period of the step 104 through step 106, a process for supplying the process medium to the process vessel, a process for refluxed the process medium to the medium supply part, and a process for depositing on the wafer W proceed substantially in parallel. Because of this, the steps 104 through 106 contribute to deposition.

Next, a process for completing the deposition is discussed with reference to FIG. 3.

After the deposition process shown in FIG. 2 is implemented for a designated time so that the Cu film is formed on the wafer, the deposition process is finished as shown in FIG. 3.

Referring to FIG. 3, in step 107, the valves 15A and 16A are closed so that supply of the process medium (reflux of the process medium) is stopped. The back pressure valve 20A is opened so that the process medium in the process vessel 11 is discharged from the medium discharge path 20. In this case, in order to prevent the discharged medium from having a high pressure, it is controlled by using the back pressure valve 20A and a fed-back value from the pressure gauge 16C so that the medium has a designated pressure.

In step 108, the valve 17A is opened. It is preferable that CO₂ in the supercritical state be introduced to the process vessel 11. Adjusting pressures in the medium reflux path and the process vessel 11 to designated pressures by the back pressure valve 20A, the precursor remaining in the process vessel 11 and the medium reflux path and the by-product are discharged with CO₂ from the medium discharge path 20.

In this case, CO₂ in the supercritical state has the high dissolution of the precursor and good diffusion. Hence, it is possible to efficiently discharge the remaining precursor and by-product. Furthermore, it is possible to purge the medium supply part 13 by opening the valves 18A and 16A.

Next, after purging is completed, in step 109, the valve 17A is closed and opening of the back pressure valve 20A is adjusted. As a result of this, the pressures in the process vessel 11 and the medium supply part 13 are gradually turned back to atmospheric pressure. In step 110, the deposition process is completed.

In this embodiment, Cu²⁺(hfac)₂ is used as the precursor for forming the Cu film. The precursor is not limited to Cu²⁺(hfac)₂. For example, a metal complex addition product (adduct) made by adding a molecular substance including at least one selected from a group including organic silane having an electron donative association or carbohydrate to a metal complex made by coordinating two β-diketonato ligands to diatomic Cu ions or a metal complex made by coordinating one β-diketonato ligand to a monatomic Cu ion, may be used as the precursor.

Furthermore, an organometallic complex including at least either a diatomic Cu ion or a monatomic Cu ion, an organometallic complex addition product, an organic mixture including at least either the organometallic complex or the organometallic complex addition product, may be used as the precursor.

For example, Cu²⁺(acac)₂, Cu²⁺(tmhd)₂, and Cu⁺(hfac)(tmvs) may be used as the precursor for depositing Cu. It is possible to obtain the same result by using any of the above-mentioned precursors as the result obtained by using Cu²⁺(hfac)₂.

A film deposited on the wafer is not limited to the Cu film. A metal film such as tantalum, tantalum nitride, titanium nitride, tungsten, or tungsten nitride, or a metal chemical compound film may be formed. These metal films or metal chemical compound films may be used as a Cu diffusion prevention film in a case where Cu wiring is formed on the fine pattern. It is possible to efficiently form the Cu diffusion prevention film on the fine pattern and the same effect as the effect obtained in a case where the Cu film in this embodiment is formed can be obtained.

The medium used in the supercritical state is not limited to CO₂. For example, NH₃ may be used so that a metal nitride film can be formed.

### Third Embodiment

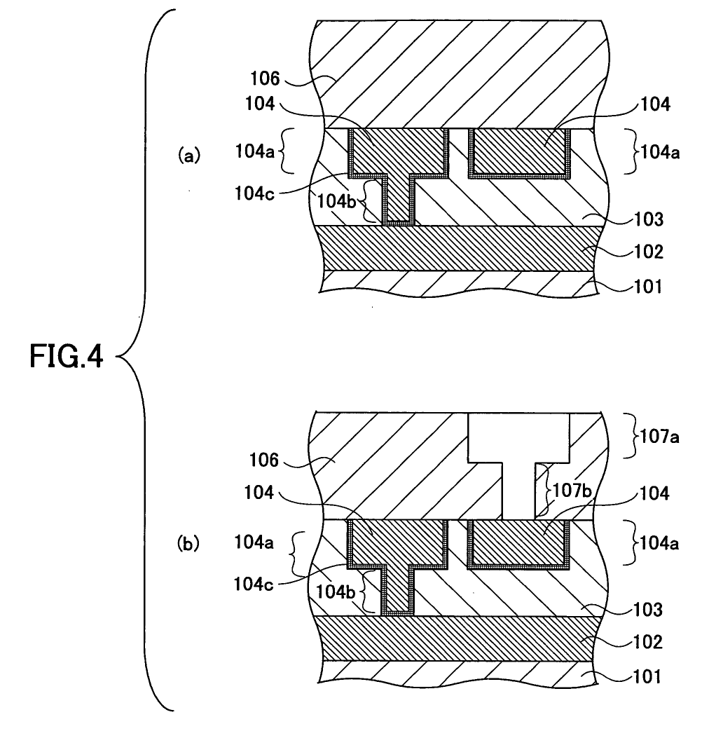

Next, an example for forming a semiconductor device using the method shown in FIG. 2 and FIG. 3 is shown in FIG. 4 through FIG. 6.

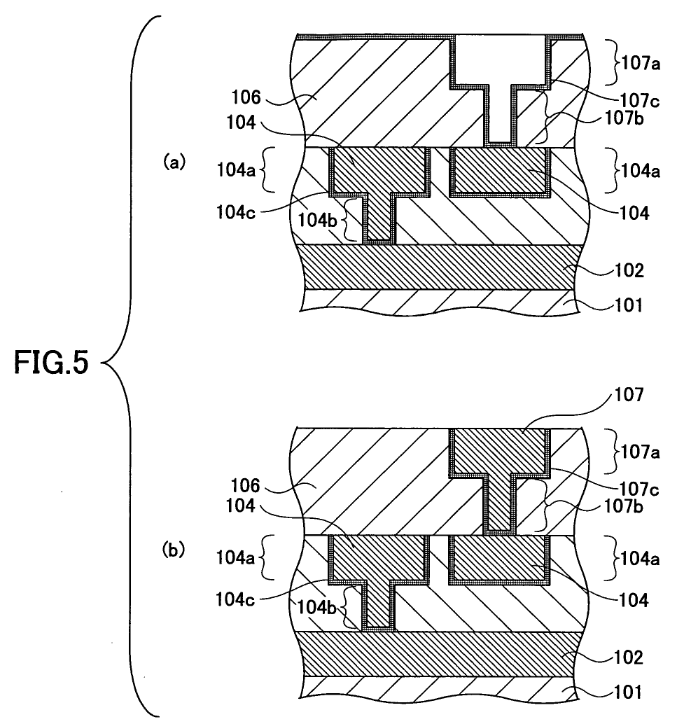

FIG. 4-(a), FIG. 4-(b), FIG. 5-(c), and FIG. 5-(d) show manufacturing steps of a semiconductor device using the method shown in FIG. 2 and FIG. 3.

Referring to FIG. 4-(a), an insulation film such as a silicon oxide film 101 is formed so as to cover an element such as a MOS transistor formed on a semiconductor substrate made of silicon. Furthermore, a wiring layer (not shown in FIG. 4) made of W, for example, electrically connected to the element and a wiring layer 102 made of Cu, for example, connected to the wiring layer are formed.

A first insulation layer 103 is formed on the silicon oxide film 101 so as to cover the Cu film 102. A groove forming part 104a and a hole forming part 104b are formed in the insulation layer 103. A Cu layer 104 as a wiring layer is formed in the groove forming part 104a and the hole forming part 104b and electrically connected to the Cu layer 102.

A barrier 104c is formed at a contact surface of the first insulation layer 103 and the Cu layer 104 and a contact surface of the Cu layer 102 and the Cu layer 104. The barrier layer 104c prevents Cu from diffusing from the Cu layer 104 to the first insulation layer 103. Adhesion of the Cu layer 104 and the first insulation layer 103 are improved by the barrier layer 104c.

The barrier layer 104c is made of metal and a metal nitride film, such as Ta and TaN. Furthermore, a second insulation film 106 is formed so as to cover an upper part of the Cu layer 104 and the first insulation layer 103. In this embodiment, a Cu layer and a barrier layer are formed by the second insulation layer 106 by applying a deposition method of the present invention.

In the process shown in FIG. 4-(b), the groove forming part 107a and a hole forming part 107b are formed in the second insulation layer by a dry etching method.

Next, in a process shown in FIG. 5-(c), by using a method similar with a method shown in FIG. 2 and FIG. 3, a barrier layer 107c is deposited on the second insulation layer 106 and an exposure surface of the Cu layer 104. The barrier layer 107c is made of Ta film and TaN in this case. For example, TaF₅, TaCl₅, TaBr₅, TaI₅, (C₅H₅)₂TaH₃, (C₅H₅)₂TaCl₃, PDMAT (Pentakis (dimethylamino) Tantalum), [(CH₃)₂N]₅Ta)) or PDEAT(Pentakis(diethylamino)Tantalum), [(C₂H₅)₂N]₅Ta)) may be used as the precursor. CO₂ or NH₃ is used as the medium in the supercritical state so that the barrier layer made of Ta/TaN is formed.

Furthermore, as described above, in this process, since CO₂ or NH₃ in the supercritical state is used, it is possible to obtain good diffusion and form the barrier film 107c on the hole forming part 107b and a bottom part and a side wall part of the groove forming part 107a at good coverage.

Next, as shown in FIG. 5-(d), by using a method similar with a method shown in FIG. 2 and FIG. 3, it is possible to form the Cu layer 107 on the barrier layer 107c. As described above, since CO₂ in the supercritical state is used and CO₂ in the supercritical state where a Cu deposition precursor is dissolved has a good diffusion, it is possible to form the Cu layer 107 on the fine hole forming part 107b and the bottom part and the side wall part of the grove forming part 107a at good coverage. Furthermore, after this process, it is possible to form a 2+n (n: natural number)th insulation layer on an upper part of the second insulation layer and form Cu wiring on each of the insulation layers by using the deposition method of the present invention. In addition, it is possible to apply the present invention to form the barrier layer formed on the first insulation layer and the Cu layer 104.

The present invention is not limited to these embodiments, but variations and modifications may be made without departing from the scope of the present invention.

This patent application is based on Japanese Priority Patent Application No. 2003-430575 filed on Dec. 25, 2003, the entire contents of which are hereby incorporated by reference.

1. A deposition apparatus for supplying a process medium including a medium in a supercritical state and a precursor to a processed substrate so that the processed substrate is deposited on, comprising:
a process vessel;
a support stand which is provided in the process vessel, is configured to support the processed substrate, and include a heating part;
a medium supply part which is connected to the process vessel via a medium supply path and supplies the process medium to the process vessel; and
a medium reflux path configured to reflux the process medium supplied to the process vessel to the medium supply part;
wherein the medium supply part includes a first temperature control part configured to control a temperature of the process medium.

2. The deposition apparatus, as claimed in claim 1,
wherein the temperature control part cools the process medium.

3. The deposition apparatus, as claimed in claim 1,
wherein the temperature control part heats the process medium.

4. The deposition apparatus, as claimed in claim 1,
wherein a compressing part configured to compress the process medium is provided in the medium supply path.

5. The deposition apparatus, as claimed in claim 1,
wherein a compressing part configured to compress the process medium is provided in the medium reflux path.

6. The deposition apparatus, as claimed in claim 1, further comprising:
a medium discharge path configured to discharge the process medium by controlling a pressure of the process medium.

7. The deposition apparatus, as claimed in claim 1,
wherein a second temperature control part is provided at the process vessel.

8. The deposition apparatus, as claimed in claim 1,
wherein a third temperature control part is provided at the medium supply path or the medium discharge path.

9. The deposition apparatus, as claimed in claim 1,
wherein the medium in the supercritical state is CO₂.

10. The deposition apparatus, as claimed in claim 1,
wherein the precursor includes a material selected from the group consisting of Cu²⁺(hfac)₂, Cu²⁺(acac)₂, Cu²⁺(tmhd)₂, and Cu⁺(hfac)(tmvs).

11. A deposition method for depositing on a processed substrate supported in a process vessel, comprising the steps of:
a) supplying a process medium including a medium in a supercritical state and a precursor to the process vessel;
b) depositing on the processed substrate by the process medium;
c) cooling the process medium discharged from the process vessel; and
d) supplying the process medium cooled in the step c) to the process vessel.

12. The deposition method, as claimed in claim 11,
wherein deposition is implemented by a chemical reaction due to heat of the precursor in the step b).

13. The deposition method, as claimed in claim 11,
wherein the temperature of the process vessel is controlled so as to be a temperature equal to or less than a temperature at which a chemical reaction due to heat of the precursor occurs.

14. The deposition method, as claimed in claim 11,
wherein the medium in the supercritical state is CO₂.

15. The deposition method, as claimed in claim 11,
wherein the precursor includes a material selected from the group consisting of Cu²⁺(hfac)₂, Cu²⁺(acac)₂, Cu²⁺(tmhd)₂, and Cu⁺(hfac) (tmvs).
